(19) United States
(12) Patent Application Publication
(10) Pub. No.: US 2025/0329820 A1
(43) Pub. Date: Oct. 23, 2025

(54) HOUSING SYSTEM OF A BATTERY DISCONNECT UNIT AND BATTERY DISCONNECT UNIT

(71) Applicant: Robert Bosch GmbH, Stuttgart (DE)

(72) Inventor: Markus Schmitt, Tamm (DE)

(21) Appl. No.: 19/180,526

(22) Filed: Apr. 16, 2025

(30) Foreign Application Priority Data
Apr. 23, 2024 (DE) 10 2024 203 797.4

(51) Int. Cl. H01M 10/656; B60R 16/033; H01M 10/613; H01M 10/625; H01M 10/63; H01M 50/242; H01M 50/249; H01M 50/271; H01M 50/583

(52) U.S. Cl. CPC H01M 10/656; B60R 16/033; H01M 10/613; H01M 10/625; H01M 10/63; H01M 50/242; H01M 50/249; H01M 50/271; H01M 50/583; H01M 2200/103; H01M 2220/20

(57) ABSTRACT

A housing system of a battery disconnect unit has a first housing element and a second housing element, which are mechanically connected to one another by a detachable connection such that a first side surface of the first housing element and a second side surface of the second housing element lie at least partially flat against each other. The housing system further includes at least one electrical and/or electronic interface that electrically and/or electronically connects the first housing element and the second housing element.

### BACKGROUND

The invention is based on a housing system of a battery disconnect unit according to the type of the disclosure. Another object of the present invention is a battery disconnect unit.

Battery disconnect units, which may also be referred to as BDUs for short, are known from prior art. These units are used for switching the battery on and off, particularly in electric vehicles. Such battery disconnect units typically include a fuse and a relay, a pyro-fuse and a relay, or a fuse, a pyro-fuse, and a relay. Furthermore, such battery disconnect units may also include interfaces for fast charging, which is known as DC charging. In addition, such battery disconnect units typically include a battery control unit, such as a BCU, and/or a supervision unit, such as a CSC.

In electric vehicles, on-board chargers (OBCs) are also known, which may be used to charge a battery with a charging cable via the power grid, typically at 11 kW or 22 kW, which is known as AC charging.

Voltage converters, known as HV DC/DC converters, are also used in electric vehicles to provide a 12-volt supply for the on-board electrical system.

The on-board charger and the HV DC/DC converter may be provided in a common housing as a single unit, referred to as CharCon.

The aforementioned components, in particular, the battery disconnect unit and the CharCon, are typically installed together in a housing. This reduces the number of interfaces on the vehicle side and allows for handling only one component.

Furthermore, the electrical and electronic components must be cooled due to comparably high electrical currents, wherein the connection to a coolant circuit is known from the prior art.

### SUMMARY

A housing system of a battery disconnect unit with the features of the disclosure offers the advantage that a simpler design of the housing system of the battery disconnect unit may be provided.

In accordance with the invention, a housing system of a battery disconnect unit is provided for this purpose. The housing system comprises a first housing element and a second housing element, which are mechanically connected to one another by means of a detachable connection in such a way that a first side surface of the first housing element and a second side surface of the second housing element lie at least partially flat against each other. Preferably, the surfaces are in full contact. Furthermore, the housing system comprises at least one electrical and/or electronic interface that electrically and/or electronically connects the first housing element and the second housing element to each other.

At this point, it should be noted that a comparably large housing known from prior art may be dispensed with. In particular, the need for a comparably sized housing in each production step may advantageously be dispensed with. Furthermore, this may also reduce the complexity of production. In addition, there is the special advantage that repairs may be significantly simplified, for example, in case of a failure.

It should further be noted that the design of the electrical and/or electronic interface within the housing system offers the particular advantage that all contacts within the housing system may be provided in a protected manner.

It should also be noted at this point that the at least partial flat contact of the first side surface of the first housing element with the second side surface of the second housing element can be referred to as a mechanical interface. Here, the mechanical interface may be provided with a seal around it to seal the electrical and/or electronic interface.

It is advantageous when the first housing element and the second housing element are connected to each other in a force-fitting and/or form-fitting manner. Preferably, the force-fitting and/or form-fitting connection may be formed by means of screw connections. This provides the advantage of connections that may be coupled and uncoupled several times, which may simplify both initial assembly and repair. Such screw connections may be formed both within an interior space of the first housing element and the second housing element, and outside an interior space of the first housing element and the second housing element.

Screw connections configured in an internal space should be sealed accordingly if necessary. An opening of at least one lid element of one of the two housing elements is required for the screw connection in an interior space of the first housing element or the second housing element. Such lid elements may have a contact system so that when the respective lid element is opened, a current flow may be interrupted. Due to the necessity of opening at least one lid element, tamper protection may preferably also be configured.

Screw connections configured outside the internal space may be formed, for example, within a housing wall of the first housing element or the second housing element.

In particular, a combination of a screw connection in an interior and a screw connection on an exterior is also possible.

The screwing direction preferably corresponds to the joining direction of the two housing elements. Of course, screwing directions at other angles are also conceivable.

In addition, the first housing element and/or the second housing element may include multiple alignment pins, each of which may engage an opening of the respective other housing element in a manner that provides more reliable positioning of the two housing elements relative to each other. In particular, an offset between the two housing elements may be reduced.

Furthermore, in addition to forming the screw connection, the two housing elements could also be connected using a tongue-and-groove system.

It is beneficial when the detachable mechanical connection is formed exclusively in a common interior of the first housing element and the second housing element. This should be understood to mean that the detachable mechanical connection is inaccessible from the exterior of the housing system of the battery disconnect unit without opening a lid element, or is substantially completely surrounded by the housing walls of the two housing elements. In particular, such a connection may be designed as a flange connection. At least one lid element must be opened to form the connection.

It is advantageous when the first housing element includes a first lid element and when the second housing element includes a second lid element. Here, respective lid elements are designed to reversibly close the respective housing element. In particular, the first lid element serves to close the first housing element and the second lid element serves to close the second housing element. This simplifies both initial assembly and repair. Furthermore, this allows corresponding components to be inserted into the respective housing elements.

It is particularly beneficial when the first housing element and/or the second housing element include at least one mechanical interface configured for mechanical connection to a vehicle. Preferably, the first housing element includes a plurality of first mechanical interfaces, in particular, two first mechanical interfaces, and the second housing element includes a plurality of second mechanical interfaces, in particular, two second mechanical interfaces. Furthermore, a mechanical interface is preferably arranged immediately adjacent to the detachable mechanical connection between the first housing element and the second housing element. This may reduce bending stress. For example, the detachable mechanical connection may preferably be configured directly between a first mechanical interface of the first housing element and a second mechanical interface of the second housing element.

It is particularly beneficial when the housing system further includes at least one hydraulic interface that connects the first housing element and the second housing element in a fluid-conducting manner. In particular, the hydraulic interface is arranged in the area of a bottom, which is arranged opposite the respective lid element, for example, of the respective housing element. In particular, the at least one hydraulic interface may also be configured outside the internal space so that sealing may preferably be dispensed with. In particular, no temperature control fluid may enter the interior in the event of a failure, for example, in the event of leaks.

Furthermore, a hydraulic interface offers the particular advantage that additional connections may be dispensed with, for example, by means of pipes or tubes.

Preferably, alignment pins or openings already described are arranged immediately adjacent to the hydraulic interface so that comparably smaller tolerances may be provided here.

Advantageously, a first tempering structure is formed within the first housing element, through which temperature control fluid is able to flow, and a second tempering structure is formed within the second housing element, through which temperature control fluid is able to flow. The first temperature control structure and the second temperature control structure are connected to each other in a fluid-conducting manner by means of the at least one hydraulic interface.

This allows for reliable temperature control to be established. Furthermore, the temperature control may be reliably configured within the housing system, with only one connection for the inlet of the temperature control fluid and only one connection for the outlet of the temperature control fluid, which may be adapted to the requirements of a vehicle-side interface, for example.

Furthermore, the housings may comprise multiple temperature control structures that may be flowed through in parallel and/or in series.

Preferably, the first housing element and/or the second housing element includes high-voltage interfaces and/or low-voltage interfaces. These serve as electrical interfaces for the high-voltage and/or low-voltage connections and terminals and may be formed at desired positions. Furthermore, it is also possible to form the electrical and/or electronic interface at a desired position.

It should be noted that the first housing element and the second housing element are each designed as die-cast aluminum housings.

The object of the present invention is also a battery disconnect unit with a housing system as described above, wherein a battery disconnect unit, a control unit and/or a supervision unit are accommodated in the first housing element, and a voltage converter is accommodated in the second housing element.

### BRIEF DESCRIPTION OF THE DRAWINGS

Exemplary embodiments of the invention are shown in the drawings and explained in more detail in the following description.

Shown are:

FIG. 1 a schematic top view of an embodiment of a housing system of a battery disconnect unit according to the invention,

FIG. 2 a schematic side view of an embodiment of a housing system of a battery disconnect unit according to the invention,

FIG. 3 a sectional view of a mechanical interface of an embodiment of a housing system of a battery disconnect unit according to the invention, and

FIG. 4 bottoms of the housing elements of an embodiment of a housing system of a battery disconnect unit according to the invention in a schematic top view.

### DETAILED DESCRIPTION

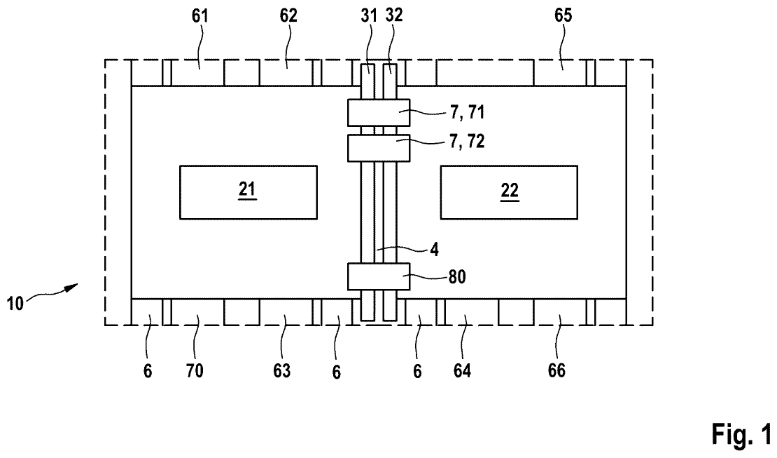

FIG. 1 shows a schematic top view of an embodiment of a housing system 10 of a battery disconnect unit 1 according to the invention.

The housing system 10 comprises a first housing element 21 and a second housing element 22. The first housing element 21 and the second housing element 22 are mechanically connected to each other by means of a detachable connection 4 in such a way that a first side surface 31 of the first housing element 21 and a second side surface 32 of the second housing element 22 are configured to lie flat against each other according to FIG. 1.

According to the embodiment of the housing system 10 shown in FIG. 1, the first housing element 21 and the second housing element 22 are connected to each other in a force-fit and/or form-fit manner. The mechanical connection 4, which is thus detachably formed, is only formed in a common interior of the first housing element 21 and the second housing element 22.

The housing system 10 further comprises electrical and/or electronic interfaces 7. These are used for an internal electrical and/or electronic connection of the first housing element 21 and the second housing element 22. In particular, the housing system 10 has a high-volt interface 71 and a low-volt interface 72. Thus, the first housing element 21 and the second housing element 22 are electrically and/or electronically connected to each other.

The first housing element 21 and the second housing element 22 further comprise a plurality of mechanical interfaces 6, which are configured to mechanically connect the housing system 10 to a vehicle not shown in the figures.

Further, the housing element 10 comprises a hydraulic connector 70 which forms a hydraulic interface to such a vehicle, and which may, in particular, include an inflow and an outflow.

In addition, the housing system 10 comprises a plurality of electrical and/or electronic connections, in particular, high-volt electrical interfaces and/or low-volt interfaces.

For example, the housing system 10 comprises a low-volt interface 61, which is configured to connect to a supervision unit.

For example, the housing system 10 includes a low-voltage interface 62, which is configured to establish a connection to an on-board power system.

For example, the housing system 10 includes a high-voltage interface 63, which is configured to enable charging using alternating current.

For example, the housing system 10 includes a high-voltage interface 64, which is configured to enable DC charging.

For example, the housing system 10 includes a high-voltage interface 65, which is configured as an interface to a battery.

For example, the housing system 10 includes a high-voltage interface 66, which is configured as an interface to a high-voltage consumer.

FIG. 1 also shows a hydraulic interface 80, which connects the first housing element 21 and the second housing element 22 in a fluid-conducting manner.

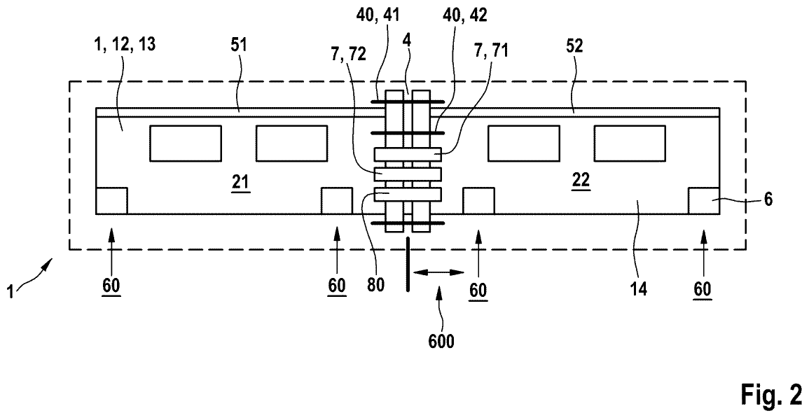

FIG. 2 shows a schematic side view of an embodiment of a housing system 10 of a battery disconnect unit 1 according to the invention.

Here, the first housing element 21 and the second housing element 22 may be seen initially.

The first housing element 21 is reversibly closed by means of a first lid element 51 and the second housing element 22 is reversibly closed by means of a second lid element 52.

Furthermore, the mechanical interfaces 6 may also be seen, which are particularly affected by the forces 60 shown. Immediately adjacent to the mechanical connection 4, a mechanical interface 6 of the respective housing elements 21, 22 is arranged so that the impacting bending moments may be reduced overall. In particular, such mechanical interfaces 6 are each arranged at a distance of 600 from the mechanical connection 4.

In addition, screw connections 40 may be seen in FIG. 2, which connect the two housing elements 21 and 22 to each other. A first screw connection 41 is arranged within an internal space formed by the two housing elements 21 and 22, and a second screw connection 42 is arranged outside of this internal space.

In the first housing element 21, for example, there is a battery disconnect unit 1, a control unit 12, and a supervision unit 13. For example, a voltage transformer 14 is accommodated in the second housing element 22.

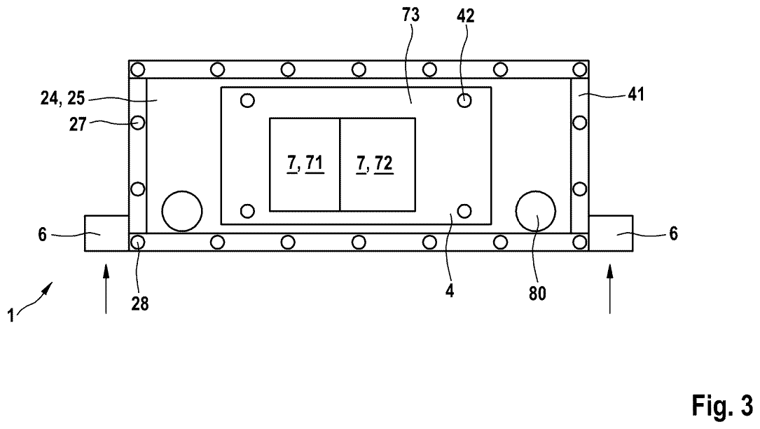

FIG. 3 shows a mechanical interface 4 of an embodiment of a housing system 10 of a battery disconnect unit 1 according to the invention in a sectional view.

First, the high-voltage interface 71 and the low-voltage interface 72 may be seen, which are circumferentially surrounded by a seal 73.

In addition, first screw connections 41 and second screw connections 42, which are configured according to FIG. 2, may be seen.

The hydraulic interfaces 80 are arranged within a first housing wall 23 of the first housing element 21 and a second housing wall 24 of the second housing element 22.

Furthermore, alignment pins 27 are shown, which may engage with corresponding openings 28 of the respective other housing element 21 or 22. The arrangement shown in FIG. 3 is merely exemplary.

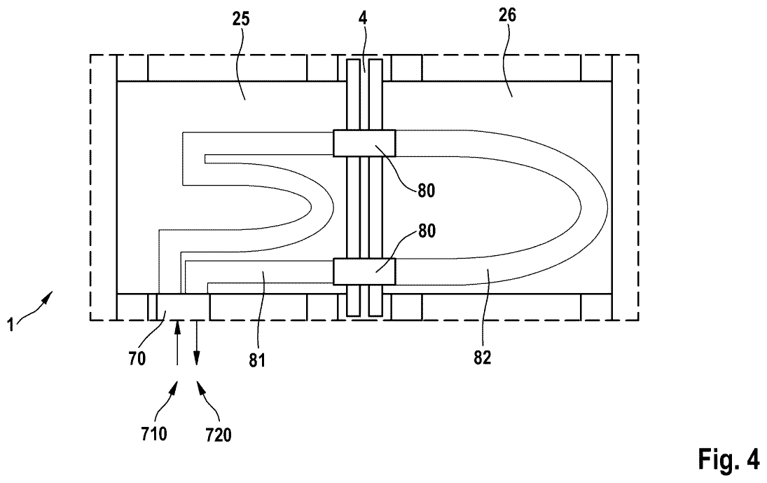

FIG. 4 shows the bottoms of the housing elements 21, 22 of an embodiment of a housing system 10 of a battery disconnect unit 1 according to the invention in a schematic top view.

In particular, the first housing element 21 has a first bottom 25 and the second housing element 22 has a second bottom 26. The two bottoms 25, 26 are arranged here opposite their respective lid elements 23, 24.

A first temperature control structure 81 is formed within the first housing element 21 or within its bottom 25, which is configured to allow temperature control fluid to flow through it.

Within the second housing element 22 or within its bottom 26, a second temperature control structure 82 is formed, which is configured to allow temperature control fluid to flow through it.

The first temperature control structure 81 and the second temperature control structure 82 are connected to each other in a fluid-conducting manner by means of hydraulic interfaces 80.

Furthermore, the hydraulic connection 70 is shown, which forms a hydraulic interface to a vehicle, and which may include an inflow 710 and an outflow 720.

1. A housing system of a battery disconnect unit (1) having a first housing element (21) and a second housing element (22), which are mechanically connected to each other by a detachable connection (4) such that a first side surface (31) of the first housing element (21) and a second side surface (32) of the second housing element (22) lie at least partially against each other, wherein the housing system (10) further comprises at least one electrical and/or electronic interface (7), which electrically and/or electronically connects the first housing element (21) and the second housing element (22).

2. The housing system of a battery disconnect unit (1) according to claim 1, wherein the first housing element (21) and the second housing element (22) are connected to each other in a force-fitting and/or form-fitting manner.

3. The housing system of a battery disconnect unit (1) according to claim 1, wherein the detachable connection (4) is formed exclusively in a common interior of the first housing element (21) and the second housing element (22).

4. The housing system of a battery disconnect unit (1) according to claim 1, wherein the first housing element (21) comprises a first cover element (51) and the second housing element (22) comprises a second cover element (52), which are each configured for reversibly closing the respective housing element (21, 22).

5. The housing system of a battery disconnect unit (1) according to claim 1, wherein the first housing element (21) and/or the second housing element (22) comprise at least one mechanical interface (6) configured for mechanical connection to a vehicle.

6. The housing system of a battery disconnect unit (1) according to claim 1, wherein the housing system (10) further comprises at least one hydraulic interface (80) that connects the first housing element (21) and the second housing element (22) to each other in a fluid-conducting manner.

7. The housing system of a battery disconnect unit (1) according to claim 6, wherein within the first housing element (21) a first temperature control structure (81), through which temperature control fluid may flow, is formed, and
wherein within the second housing element (22) a second temperature control structure (82), through which temperature control fluid may flow, is formed,
wherein the first temperature control structure (81) and the second temperature control structure (82) are connected to each other in a fluid-conducting manner by the hydraulic interface (80).

8. The housing system of a battery disconnect unit (1) according to claim 1, wherein the first housing element (21) and/or the second housing element (22) comprise high-voltage interfaces and/or low-voltage interfaces.

9. A battery disconnect unit with a housing system (10) according to claim 1, wherein the first housing element (21) contains a battery disconnect unit (1), a control unit (12) and/or a supervision unit (13), and the second housing element (22) contains a voltage converter (14).
